(19) United States
(12) Patent Application Publication
(10) Pub. No.: US 2013/0285720 A1
(43) Pub. Date: Oct. 31, 2013

(54) MULTIPLE CHANNEL PHASE DETECTION

(71) Applicant: Rafel Jibry, Bristol (GB)

(72) Inventor: Rafel Jibry, Bristol (GB)

(21) Appl. No.: 13/456,574

(22) Filed: Apr. 26, 2012

(51) Int. Cl. H03L 7/06

(52) U.S. Cl. 327/156

(57) ABSTRACT

A signal processing device to utilize multiple channel phase detection includes a first phase detector for a first Phase Locked Loop (PLL) of a first channel, the first phase detector to generate phase error information from an input of the first channel. The device also includes a second phase detector of a second PLL of a second channel, the second phase detector to generate phase error information from an input of the second channel. Both the first PLL and the second PLL are to receive phase error information from both the first phase detector and the second phase detector.

### BACKGROUND

As the use of digital data increases, the capacity of data storage devices to hold this data and the corresponding methods for achieving higher capacity are improving. For example, methods for writing to tape backup drives are such that more bits are being fit within a smaller volume of magnetic tape. When using such methods, the magnetic characteristics that indicate the value of a particular bit are spread across multiple bit spaces in the read back signal. Thus, to read the value of a particular bit from a particular bit space, a reading device has to take into account the magnetic characteristics of neighboring bit spaces. This overlap of bit encoding results in Inter-Symbol Interference (ISI) within the read back signal. Partial Response Maximum Likelihood (PRML) techniques may be used to decode the individual bits encoded using such techniques.

### BRIEF DESCRIPTION OF THE DRAWINGS

The accompanying drawings illustrate various examples of the principles described herein and are a part of the specification. The drawings are merely examples and do not limit the scope of the claims.

FIG. 1A is a diagram showing an illustrative signal processing device, according to one example of principles described herein.

FIG. 1B is a diagram showing an illustrative timing recovery block, according to one example of principles described herein.

FIG. 2 is a diagram showing illustrative multiple channel phase detection, according to one example of principles described herein.

FIG. 3 is a diagram showing illustrative global collation, according to one example of principles described herein.

FIG. 4 is a diagram showing an illustrative phase locked loop structure, according to one example of principles described herein.

FIG. 5 is a flowchart showing an illustrative method for utilizing multiple channel phase detection, according to one example of principles described herein.

Throughout the drawings, identical reference numbers designate similar, but not necessarily identical, elements.

### DETAILED DESCRIPTION

During a reading process of a magnetic tape, a sensor detects the magnetic flux direction as the magnetic tape passes by. The sensor creates an electrical signal of a particular frequency and phase. The electrical signal is modulated by the magnetic flux detected by the sensor. This signal passes through a Phase Locked Loop (PLL) to keep the phase of the reading device locked appropriately to allow processing of the corresponding digital signal. A PLL includes a phase detector, which measures the phase error of the incoming signal.

Different orders of phase detectors may be used in the PLLs of reading devices for data signals. A higher order phase detector is used when the ISI of the input signal is greater. Alternatively, a lower order phase detector is typically used when there is a smaller ISI in the input signal. These different types of phase detectors have different benefits and drawbacks and thus the designer of the reading system balances these tradeoffs for the design purposes.

A lower order phase detector may be used when there is less ISI in the input signal. One example of a lower order phase detector is a PR4 phase detector. PR4 is a type of Partial Response Maximum Likelihood (PRML) method. PR4 exhibits a faster loop but has a lower channel Signal to Noise Ratio (SNR) when the ISI is greater.

A higher order phase detector may be used when the ISI of the input signal is greater. One example of a higher order phase detector is an Extended Partial Response 4 (EPR4) phase detector. EPR4 phase detectors exhibit a slower loop bandwidth but have a higher SNR when the ISI is greater.

These different types of phase detectors have different benefits and drawbacks for different situations. For example, a lower order phase detector is generally more efficient at deriving valid phase information. Specifically, a lower order phase detector may be able to detect a valid phase error for each bit synchronous sample of a signal. However, lower order phase detectors often exhibit a higher SNR when the ISI is large. In contrast, higher order phase detectors have a better SNR when the ISI is large. However, higher order phase detectors are less efficient at providing phase error information from bit synchronous samples. For example, a higher order phase detector may provide valid phase information, on average, once every five samples.

In light of this and other issues, the present specification discloses methods and systems for utilizing multiple channel phase detection. In many situations, a signal processing device is used to process multiple signals from different channels in parallel. These channels are often nominally at the same frequency and possibly phase. According to certain illustrative examples, in such situations, the signal processing component for a single channel can utilize phase error information from its own channel as well as from other channels.

Particularly, the phase locked loop for a specific channel can utilize information from its corresponding higher order phase detector as well as the higher order phase detector from other channels. Each channel may operate in such a manner and utilize phase error information from other channels. As each of the phase detectors from multiple channels provides valid phase error information at different intervals, a combination of this data provides a steadier and more efficient stream of phase error information.

Through use of methods and systems embodying principles described herein, a more effective and efficient manner of processing data signals is realized. Specifically, higher order signal processing devices can utilize the higher order phase detectors and achieve higher SNR implementations. By using phase error information from other channels, the higher order phase detectors can maintain a steadier stream of valid phase error information.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an example” or similar language means that a particular feature, structure, or characteristic described in connection with that example is included as described, but may not be included in other examples.

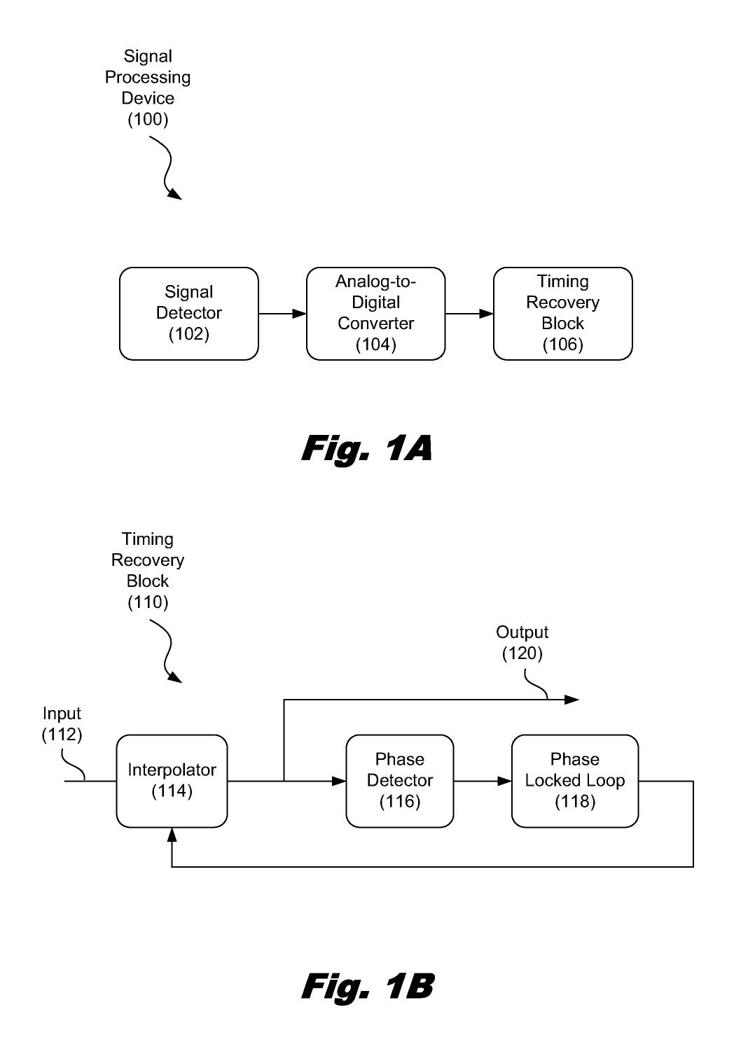

Referring now to the figures, FIG. 1A is a diagram showing an illustrative signal processing device (100). According to certain illustrative examples, the signal processing device (100) includes a signal detector (102), an Analog-to-Digital Converter (ADC), and a timing recovery block (106). The signal processing device may be designed to process a variety of different types of signals. This specification will use an example of signals read from a magnetic tape drive.

The signal detector (102) is a sensor that creates an electrical signal based on the sensed information. For example, as the magnetic tape passes by a reading device, the magnetic flux from that tape that represents encoded data will cause the reader to produce an electric signal. Within this signal is the encoded data that was written to the tape drive.

This signal is typically in an analog form. An analog signal is one that takes on a continuum of values. In contrast, a digital signal is one that takes on a discrete set of values or measurements at discrete time intervals. The ADC (104) converts the analog signal received by the signal detector into a digital signal.

The timing recovery block (106) is used to reconstruct digital samples at times or phase corresponding to bit times or phases such that the data from the signal can be read accurately. Without the timing recovery block, the signal processing device would not be taking signal measurements at the time intervals that correspond to bits encoded within the data stream.

FIG. 1B is a diagram showing an illustrative timing recovery block (110). According to certain illustrative examples, the timing recovery block includes an interpolator (114), a phase detector (116) and a PLL (118). The timing recovery block ensures that the phase of the output signal (120) matches the phase of the data in the input signal (112).

The interpolator (114) is used to create a new set of discrete data points from an existing set of data points. For example, the ADC may be designed to sample data at a particular rate. The interpolator (114) uses various functions to make a relatively accurate estimate of the signal value in between sampled points to create the new set of points.

A phase detector (116) determines the phase error in the output signal. This phase error is used by the PLL (118) to feed information back to the interpolator (114). Specifically, the phase detector (116) detects the error in phase of the output signal (120). The PLL (118) uses this information to adjust the interpolator (114) so that the phase of the output signal (120) is adjusted to approach or match the ideal phase.

As mentioned above, different types of phase detectors may be used. A lower order phase detector may be used when there is a smaller ISI in the input signal. One example of a lower order phase detector is a PR4 phase detector. PR4 is a type of Partial Response Maximum Likelihood (PRML) method. PR4 exhibits a faster loop but has a lower channel Signal to Noise Ration (SNR) when ISI is greater. A higher order phase detector may be used when the ISI of the input signal is greater. One example of a higher order phase detector is an Extended Partial Response 4 (EPR4) phase detector. EPR4 phase detectors exhibit a slower loop bandwidth but allow a higher SNR implementation or lower cost implementation when ISI is large.

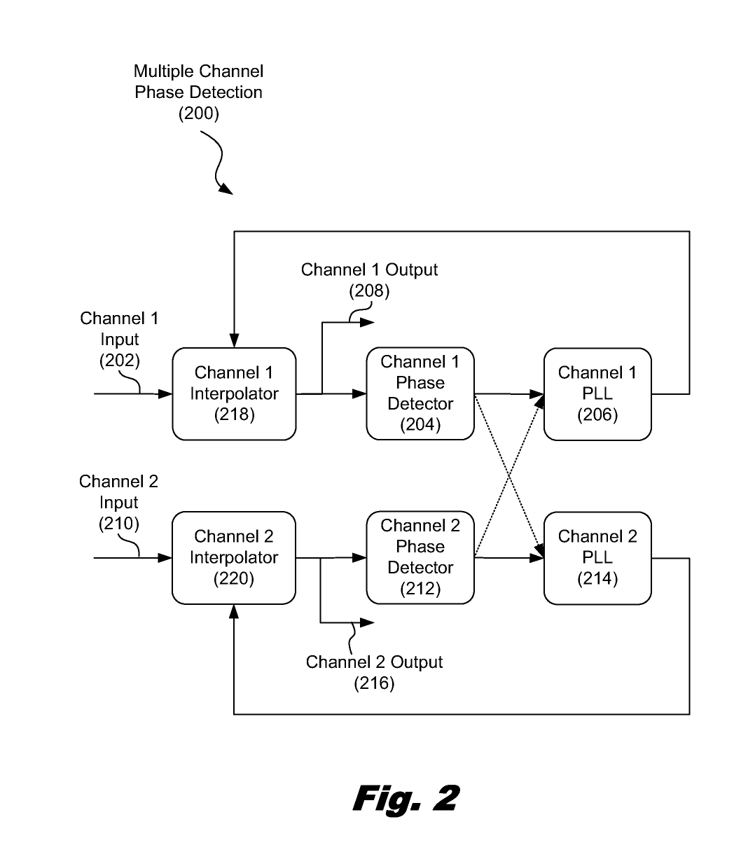

FIG. 2 is a diagram showing illustrative multiple channel phase detection (200). According to certain illustrative examples, a first channel includes an input (202), a phase detector (204), a PLL (206), and an output (208). Additionally, a second channel includes an input (210), a phase detector (212), a PLL (214), and an output (216).

The channel 1 PLL (206) receives phase error information from its corresponding phase detector (204). Assuming this phase detector (204) is a higher order phase detector, it may provide the channel 1 PLL (206) with valid phase error information, on average, once every five samples. To get better phase error information the channel 1 PLL (206) also receives phase error information from the channel 2 phase detector (212). The output (208) of the channel 1 PLL (206) is then fed back to the channel 1 interpolator (218). By utilizing phase error information from both phase detectors (204, 212), the channel 1 PLL (206) receives valid phase error information more than once every five samples. For example, it is possible that the channel 1 phase detector (206) may receive valid phase information, on average, once every three samples.

Likewise, the channel 2 PLL (214) receives phase error information from its corresponding phase detector (212). Assuming this phase detector (212) is also a higher order phase detector, it may provide the channel 2 PLL (214) with valid phase error information, on average, once every five samples. To get better phase information the channel 2 PLL (214) also receives phase error information from the channel 1 phase detector (204). The output (216) of the channel 2 PLL (214) is then fed back to the channel 2 interpolator (220).

In some cases, the PLL of a particular channel is responsible for collating the phase error information from the phase detector of that channel as well as from phase detectors of other channels. This collation process may involve determining if the phase information from a particular phase detector is valid. In one example, the phase detector stream may be tagged to indicate validity. Alternatively, the collation process may be performed by a global device.

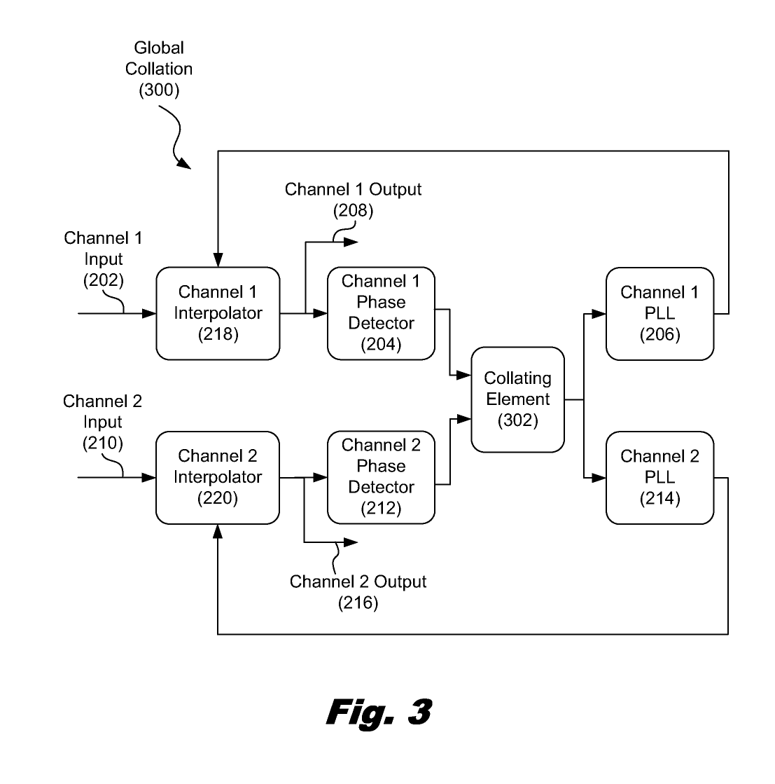

FIG. 3 is a diagram showing illustrative global collation (300). According to certain illustrative examples, the PLLs (206, 212) of each channel receive phase error information from a global collating element (302). The global collating element (302) receives phase error information from each of the phase detectors (204, 212).

Thus, the channel 1 PLL (206) receives a combination of phase error information compiled by the collating element (302). The output (208) of the channel 1 PLL (206) is then fed back to the channel 1 interpolator (218). The channel 1 phase detector (204) then provides phase error information to the collating element (302) which performs the collating function. Likewise, the channel 2 PLL (214) receives a combination of phase error information compiled by the collating element (302). The output (216) of the channel 2 PLL (214) is then fed back to the channel 2 interpolator (220). The channel 2 phase detector (212) then provides phase error information to the collating element (302).

The collating element (302) can be designed to weight the phase error information from the multiple channels. For example, based on various metrics of the data streams from multiple channels, the collating element (302) may give preference to phase error information from specific channels. This weighting may vary in real time as the metrics change. One example of a metric used in the weighting determination may be the SNR of a particular channel. If no global collating element is used, the PLLs of each channel may be designed to perform such a weighting function.

While there are two channels illustrated in FIG. 3, there may be a larger number of channels all utilizing phase error information from all the other channels. For example, a global collating element may collate phase error information from 16 different channels nominally operating on the same frequency and phase. The global collating element may then provide the collated phase error information to the PLL for each of those channels. Alternatively, each PLL may include circuitry to collate phase error information from multiple channels.

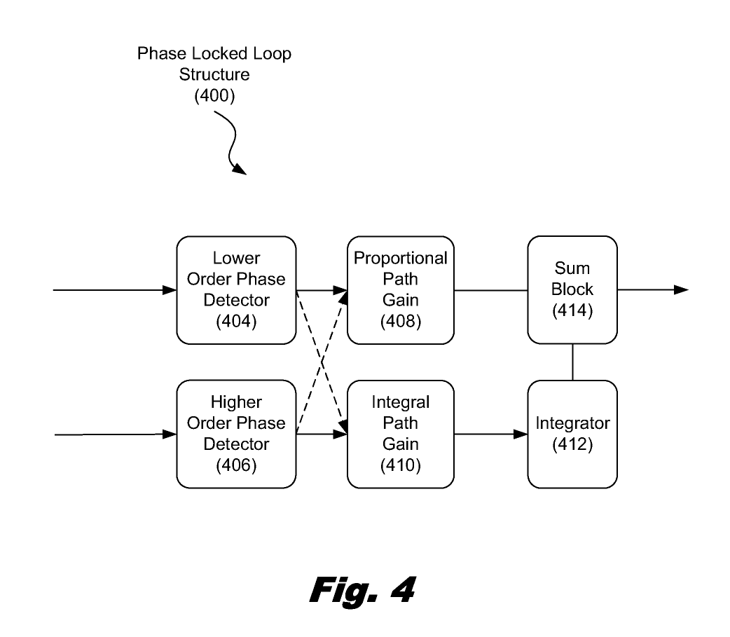

FIG. 4 is a diagram showing an illustrative phase locked loop structure. According to certain illustrative examples, a phase locked loop structure includes a proportional path gain (408), an integral path gain (410), an integrator (412), and a sum block (414). The proportional path gain (406) and the integral path gain (410) affect the feedback loop of the PLL. The proportional gain (406) produces an output that is proportional to the phase error provided by a phase detector. The integral path gain (410) and integrator (412) are used to affect the output based on the magnitude and duration of the phase difference. The sum block (414) combines the proportional path gain (408) and the integral path gain (410).

According to certain illustrative examples, a lower order phase detector (404) such as a PR4 phase detector may be used to drive the proportional path gain. This phase detector is operating on the corresponding channel and not using phase information from multiple channels. In some cases, the lower order phase detector (404) may generate phase error information from the corresponding channel rather than phase error information from multiple channels.

The integral path of the PLL can benefit from a higher order phase detector such as an EPR4 phase detector. The higher order phase detector is designed to utilize phase error information from multiple phase detectors as described above. This information is more useful to the integral path. Because the proportional path gain (408) does not benefit as much from the combined phase error information, the PLL can operate more efficiently by having a separate lower order phase detector (404) for the proportional path (408).

In some cases, the lower order phase detector (404) may drive both the proportional path gain (408) and the integral path gain (410). Alternatively, the higher order phase detector (406) may drive both the proportional path gain (408) and the integral path gain (410). Switching between use of the two different types of phase detectors (404, 406) may be done in real time for various reasons.

For example, the data written to a tape medium includes an acquisition field and a data field. The acquisition field causes the sensor reading the magnetic tape to produce an acquisition signal. The acquisition signal is a strong sinusoidal signal that makes it easier for the PLL to lock onto the frequency and phase of that signal. The data field is where the data that is intended to be stored by the user to the tape medium is actually written. The data signal resulting from sensing the data field is a heavily modulated signal with data encoded. Lower order phase detectors such as PR4 phase detectors are more effective when processing the acquisition signal, but weaker in performance when processing the data signal in the presence of large ISI.

Conversely, a higher order phase detector such as an EPR4 detector exhibits stronger performance when processing the data signal in the presence of large ISI and a weaker performance when processing the acquisition signal. Thus, the lower order phase detector (404) may be used to drive the PLL during processing of an acquisition signal and the higher order phase detector (406) may drive the PLL during processing of a data signal.

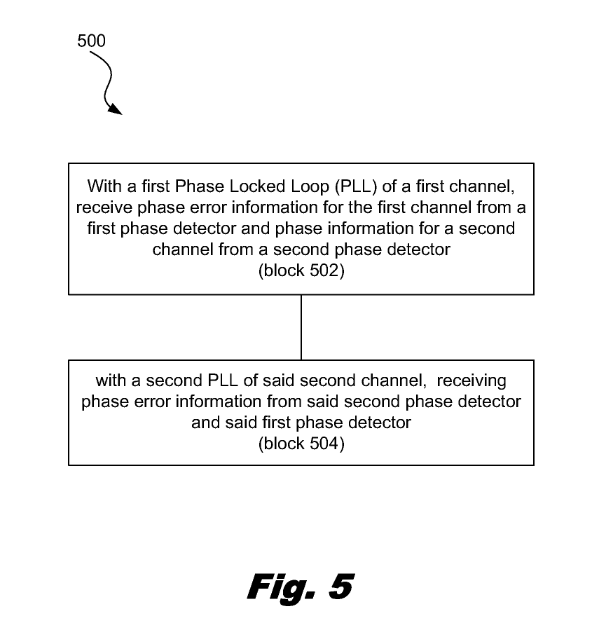

FIG. 5 is a flowchart showing an illustrative method for utilizing multiple channel phase detection. According to certain illustrative examples, the method includes, with a first Phase Locked Loop (PLL) of a first channel, receiving (block 502) phase error information for the first channel from a first phase detector and phase error information for a second channel from a second phase detector. The method further includes, with a second PLL of the second channel, receiving (block 504) phase information from the second phase detector and the first phase detector.

In conclusion, through use of methods and systems embodying principles described herein, a more effective and efficient manner of processing data signals is realized. Specifically, higher order phase detectors enable the better SNR of higher order signal processing devices to be implemented and operated reliably. By using phase error information from other channels, the higher order phase detectors can maintain a steadier stream of valid phase error information.

The preceding description has been presented only to illustrate and describe examples of the principles described. This description is not intended to be exhaustive or to limit these principles to any precise form disclosed. Many modifications and variations are possible in light of the above teaching.

1. A signal processing device to utilize multiple channel phase detection, the device comprising:
a first phase detector for a first Phase Locked Loop (PLL) of a first channel, said first phase detector to generate phase error information from an input of said first channel; and
a second phase detector of a second PLL of a second channel, said second phase detector to generate phase error information from an input of said second channel;
wherein, both said first PLL and said second PLL are to receive phase error information from both said first phase detector and said second phase detector.

2. The device of claim 1, wherein said first PLL is to collate information from said first phase detector and said second phase detector.

3. The device of claim 1, further comprising, a global collating element to collate phase information from both said first phase detector and said second phase detector to produce collated phase information for said first PLL and said second PLL.

4. The device of claim 1, wherein said first phase detector comprises a higher order phase detector.

5. The device of claim 4, wherein said higher order phase detector comprises an Extended Partial Response 4 (EPR4) phase detector.

6. The device of claim 1, wherein said first phase detector provides information for an integral path of said first PLL.

7. The device of claim 1, further comprising a lower order phase detector for said first channel, said lower order phase detector to provide phase information to a proportional path of said first PLL.

8. A method for utilizing multiple channel phase detection, the method comprising:
with a first Phase Locked Loop (PLL) of a first channel, receiving phase error information for said first channel from a first phase detector and phase error information for a second channel from a second phase detector; and
with a second PLL of said second channel, receiving phase error information from said second phase detector and said first phase detector.

9. The method of claim 8, further comprising, with said first PLL, collating phase information from both said first phase detector and said second phase detector.

10. The method of claim 8, further comprising, with a global collating element, collating phase information from both said first phase detector and said second phase detector.

11. The method of claim 10, further comprising, with said global collating element, sending collated phase information to both said first PLL and said second PLL.

12. The method of claim 8, wherein said first phase detector comprises a higher order phase detector.

13. The method of claim 8, wherein said first phase detector provides information for an integral path of said first PLL.

14. The method of claim 8, further comprising, with a lower order phase detector for said first channel, providing phase information to a proportional path of said first PLL.

15. A multiple channel phase detection system comprising:
a number of channels that are nominally operating at a same frequency, each channel comprising:
a phase detector; and
a Phase Locked Loop (PLL);
wherein each PLL for each of said channels is to receive phase error information for its respective channel and phase error information from at least one phase detector of a separate channel.
